(19) United States
(12) Patent Application Publication
(10) Pub. No.: US 2026/0161067 A1
(43) Pub. Date: Jun. 11, 2026

(54) MULTI-LAYER ABSORBER FILM FOR LITHOGRAPHY MASK BLANK

(71) Applicant: Taiwan Semiconductor Manufacturing Company, Ltd., Hsinchu (TW)

(72) Inventors: Pei-Cheng HSU, Hsinchu (TW); Ken-Hsien HSIEH, Hsinchu (TW); Sheng-Min WANG, Hsinchu (TW); Sih-Wei CHANG, Hsinchu (TW); Hsin-Chang LEE, Hsinchu (TW)

(73) Assignee: Taiwan Semiconductor Manufacturing Company, Ltd., Hsinchu (TW)

(21) Appl. No.: 18/972,579

(22) Filed: Dec. 6, 2024

(51) Int. Cl. G03F 1/22; G03F 7/00

(52) U.S. Cl. CPC G03F 1/22; G03F 7/0005

(57) ABSTRACT

The present disclosure relates to a method of fabricating a lithography mask. The method includes forming a multi-layer reflective structure over a substrate. A capping layer is formed over the multi-layer reflective structure. A buffer layer is formed over the capping layer and an absorber layer is formed over the buffer layer. The absorber layer includes at least a first absorber layer and a second absorber layer, each including a non-alloyed element, and the first absorber layer and the second absorber layer are made of different non-alloyed elements.

### BACKGROUND

The semiconductor integrated circuit (IC) industry has experienced rapid growth. Technological advances in IC materials and design have produced generations of ICs where each generation has smaller and more complex circuits than the previous generation. These advances, however, have increased the complexity of processing and manufacturing ICs and, for these advances to be realized, similar developments in IC processing and manufacturing are needed. In the course of IC evolution, functional density (i.e., the number of interconnected devices per chip area) has generally increased while geometry size (i.e., the smallest component (or line) to be created using a fabrication process) has decreased.

As the semiconductor device sizes continue to shrink, for example in the nanometer (nm) nodes, traditional lithography technologies have optical restrictions, which lead to resolution issues and may not achieve the desired lithography performance. In comparison, extreme ultraviolet (EUV) lithography achieves much smaller device sizes. Existing EUV lithography, however, may still face certain challenges. For example, the material used for the absorbing layer of existing EUV masks may be too thick, which may degrade the lithography performance of the EUV mask.

Therefore, while existing EUV lithography systems and methods have been generally adequate for their intended purposes, there remains room for improvement.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 is a schematic view of a lithography system constructed in accordance with some embodiments of the present disclosure.

FIGS. 2, 3, 4, 5, 6, 7, 8, 9, 10, and 11 illustrate cross-sectional views of a lithography mask at various stages of fabrication according to embodiments of the present disclosure.

FIGS. 12, 13, 14, 15, 16, 17, 18, 19, 20, 21, and 22 illustrate cross-sectional views of various stages of manufacturing a patterned lithography mask, according to embodiments of the present disclosure.

FIG. 23 is a flowchart illustrating a method of fabricating a lithography mask, in accordance with some embodiments of the present disclosure.

FIG. 24 is a flowchart illustrating a method of manufacturing a patterned lithography mask, in accordance with some embodiments of the present disclosure.

### DETAILED DESCRIPTION

It is to be understood that the following disclosure provides many different embodiments, or examples, for implementing different features of the present application. Specific embodiments or examples of components and arrangements are described below to simplify the present disclosure. These are, of course, merely examples and are not intended to be limiting. For example, dimensions of elements are not limited to the disclosed range or values but may depend upon process conditions and/or desired properties of the device. Moreover, the formation of a first feature over or on a second feature in the description that follows may include embodiments in which the first and second features are formed in direct contact, and may also include embodiments in which additional features may be formed by interposing the first and second features, such that the first and second features may not be in direct contact. Various features may be arbitrarily drawn in different scales for simplicity and clarity. In the accompanying drawings, some layers/features may be omitted for simplification.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. In addition, the term “made of” may mean either “comprising” or “consisting of.” Further, in the following fabrication process, there may be one or more additional operations in between the described operations, and the order of operations may be changed. In the present disclosure, the phrase “at least one of A, B and C” means either one of A, B, C, A+B, A+C, B+C or A+B+C, and does not mean one from A, one from B, and one from C, unless otherwise explained.

EUV lithography has become widely used due to its ability to achieve small semiconductor device sizes. However, conventional systems and methods of performing EUV lithography may still face various challenges. For example, conventional EUV systems employ a lithography mask configured to perform EUV lithography. Among other components, the EUV lithography mask includes an absorber layer that ensures that a pattern image contrast is maintained against a multi-layer coating by absorbing EUV light while minimizing reflection. The EUV mask patterning process depends on the proper choice of EUV mask absorber material, which can have a direct impact on the mask quality such as critical dimension (CD) control. Some conventional EUV lithography masks employ an absorber layer that may be too thick. If the absorber layer is too thick, e.g., between 45 and 70 nm, it becomes difficult to adjust the refraction index and extinction coefficient values of the EUV mask. Certain conventional absorber layers use binary alloy materials resulting in thick absorber layers which can make it difficult to obtain ideal refraction index and extinction coefficient values. Thick absorber layers can suffer from mask three-dimensional effects such as light shadowing which occurs when EUV light hits the EUV mask at an angle, leading to asymmetric shadowing and a size bias between features with different orientations. Further, thick absorber layers can deform the phase of the incident light, leading to aberration-like effects. Moreover, thick absorber layers can contribute to larger exposure energy.

To alleviate these problems discussed above, the present disclosure provides an EUV lithography mask having a multi-layer absorber layer containing pure elements that result in a thinner absorber layer. The thinner absorber layer makes it easier to adjust EUV refractive index and extinction coefficient values. In certain embodiments, the materials used in the multi-layer absorber layer provide a low refraction index in order to obtain a phase difference between light passing through the absorber region and the open area close to π (e.g., 1 to 1.2π).

Moreover, with the present disclosure, the reduced thickness of the absorber layer helps reduce the occurrence of mask three-dimensional effects, reduces exposure energy, and improves normalized image log slope (NILS). NILS is an important metric in evaluating the quality of an EUV image by measuring the steepness of the intensity transition of the normal line edge of the mask pattern, wherein the steepness directly impacts the edge definition of the resulting photoresist pattern. The various aspects of the present disclosure will be discussed below in greater detail with reference to the drawing figures.

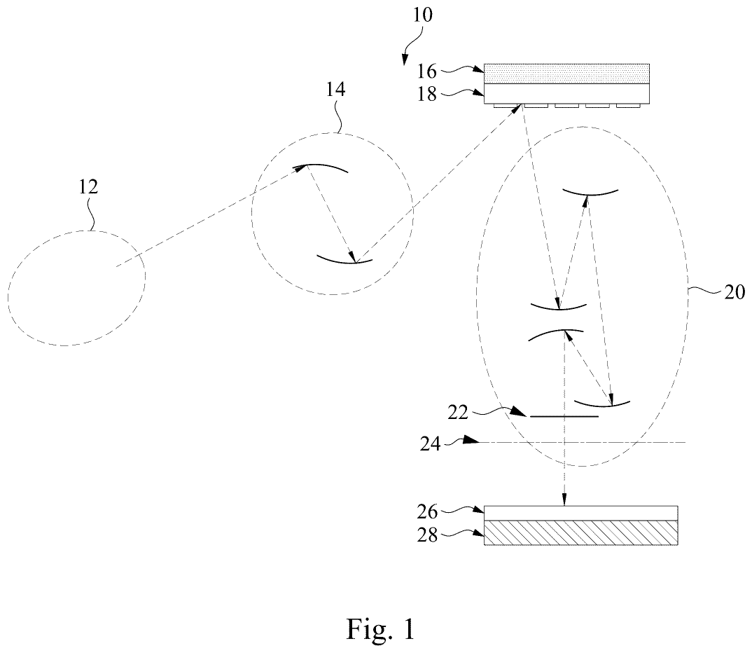

An EUV lithography system according to embodiments of the present disclosure is discussed below with reference to FIG. 1. A schematic view diagram of an EUV lithography system 10, structured in accordance with some embodiments is shown in FIG. 1. The EUV lithography system 10 is generally referred to as a scanner that is configured to perform lithography exposure processes with respective radiation source and exposure mode. The EUV lithography system 10 is designed to expose a photoresist layer by EUV light or EUV radiation. The photoresist layer is a material sensitive to the EUV light. The EUV lithography system 10 employs a radiation source 12 to generate EUV light, such as EUV light having a wavelength ranging between about 1 nm and about 100 nm. In certain examples, radiation source 12 generates EUV light with a wavelength between 10 to 121 nm. Accordingly, the radiation source 12 is also referred to as an EUV radiation source 12.

The lithography system 10 also employs an illuminator 14. In various embodiments, the illuminator 14 includes various refractive optic components, such as a single lens or a lens system having multiple lenses (zone plates) or alternatively reflective optics (for EUV lithography system), such as a single mirror or a mirror system having multiple mirrors to direct light from the radiation source 12 onto a mask stage 16, particularly to a EUV lithography mask 18 secured on the mask stage 16. The mask stage 16 is configured to secure an EUV lithography mask 18. In some embodiments, the mask stage 16 includes an electrostatic chuck (e-chuck) to secure the EUV lithography mask 18. In the present embodiment, where the radiation source 12 generates light in the EUV wavelength range, the illuminator 14 employs reflective optics. In some embodiments, the illuminator 14 includes a dipole illumination component.

In some embodiments, illuminator 14 is operable to configure the mirrors to provide proper illumination to the EUV lithography mask 18. In one example, the mirrors of the illuminator 14 are switchable to reflect EUV light to different illumination positions. In some embodiments, a stage before the illuminator 14 additionally includes other switchable mirrors that are controllable to direct the EUV light to different illumination positions with the mirrors of the illuminator 14. In certain embodiments, illuminator 14 is configured to provide an on-axis illumination (ONI) to the EUV lithography mask 18. In one example, a disk illuminator 14 with partial coherence σ being at most 0.3 is employed. In some other embodiments, the illuminator 14 is configured to provide an off-axis illumination (OAI) to the EUV lithography mask 18. For example, the illuminator 14 is a dipole illuminator. The dipole illuminator has a partial coherence σ of at most 0.3 in some embodiments.

In the embodiment of FIG. 1, the lithography system 10 is an EUV lithography system, and the EUV lithography mask 18 is a reflective mask. In the present disclosure, the terms mask, photomask, and reticle are used interchangeably to refer to the same item. One exemplary structure of the EUV lithography mask 18 is provided for illustration. The EUV lithography mask 18 includes a substrate with a suitable material, such as a low thermal expansion material (LTEM) or fused quartz. In various examples, the LTEM includes TiO₂ doped SiO₂ or other suitable materials with low thermal expansion. In some embodiments, the LTEM includes 5%-20% by weight TiO₂ and has a thermal coefficient of expansion lower than about 1.0×10⁻⁶/° C. For example, in some embodiments, the TiO₂ doped SiO₂ material of the LTEM has a coefficient of thermal expansion such that it varies by less than 60 parts per billion for every 1 degree Celsius of temperature change. Of course, other suitable materials having a thermal coefficient of expansion that is equal to or less than TiO₂ doped SiO₂ are contemplated.

The EUV lithography mask 18 also includes a multi-layer reflective structure deposited on the substrate. The multi-layer reflective structure includes a plurality of film pairs, such as molybdenum-silicon (Mo/Si) film pairs (e.g., a layer of molybdenum above or below a layer of silicon in each film pair). Alternatively, the multi-layer reflective structure includes molybdenum-beryllium (Mo/Be) film pairs, or other suitable materials that are configurable to reflect the EUV light.

The EUV lithography mask 18 includes a capping layer that is disposed on the multi-layer reflective structure for protection of the multi-layer reflective structure and/or the layers there below. According to embodiments of the present disclosure, the capping layer of the EUV lithography mask 18 includes an amorphous or polycrystalline structure. In some embodiments, a capping layer is formed on the multi-layer reflective structure. In other embodiments, the capping layer is formed by first treating the upper surface of the multi-layer reflective structure (for example by treating it with a plasma), and thereafter forming the capping layer on the treated surface of the multi-layer reflective structure.

The EUV lithography mask 18 further includes an absorption layer (also referred to as an absorber layer) deposited over the capping layer. The absorption layer is patterned to define a layer of an integrated circuit (IC). Alternatively, another reflective layer is deposited over the multi-layer reflective structure and is patterned to define a layer of an integrated circuit, thereby forming an EUV phase shift mask. The absorber layer of the present disclosure is a multi-layer structure (e.g., 2, 3, or 4 layers) including low refraction index materials that help reduce the thickness of the absorber layer, improve NILS, and reduce exposure energy.

As shown in FIG. 1, the lithography system 10 also includes a projection optics module (or projection optics box (POB) 20 for imaging the pattern of the EUV lithography mask 18 on to a target 26 (e.g., a semiconductor substrate) secured on a substrate stage 28 of the lithography system 10. The POB 20 has refractive optics (such as for UV lithography system) or alternatively reflective optics (such as for EUV lithography system) in various embodiments. The light directed from the EUV lithography mask 18, diffracted into various diffraction orders and carrying the image of the pattern defined on the mask, is collected by the POB 20. In some embodiments, the POB 20 includes a magnification of less than one (thereby the size of the “image” on a target (such as target 26 discussed below) is smaller than the size of the corresponding “object” on the mask). The illuminator 14 and the POB 20 are collectively referred to as an optical module of the lithography system 10.

The lithography system 10 also includes a pupil phase modulator 22 to modulate the optical phase of the light directed from the EUV lithography mask 18 so that the light has a phase distribution on a projection pupil plane 24. In the optical module, there is a plane with field distribution corresponding to a Fourier Transform of the object (the EUV lithography mask 18 in the present case). This plane is referred to as the projection pupil plane. The pupil phase modulator 22 provides a mechanism to modulate the optical phase of the light on the projection pupil plane 24. In some embodiments, the pupil phase modulator 22 includes a mechanism to tune the reflective mirrors of the POB 20 for phase modulation. In certain embodiments, the mirrors of the POB 20 are switchable and are controlled to reflect the EUV light, thereby modulating the phase of the light through the POB 20.

In some embodiments, the pupil phase modulator 22 utilizes a pupil filter placed on the projection pupil plane 24. A pupil filter filters out specific spatial frequency components of the EUV light from the EUV lithography mask 18. Particularly, the pupil filter is a phase pupil filter that functions to modulate the phase distribution of the light directed through the POB 20. However, utilizing a phase pupil filter is limited in some lithography systems (such as an EUV lithography system) since the materials of the phase pupil filter absorb EUV light.

As discussed above, lithography system 10 also includes substrate stage 28 to secure the target 26 to be patterned, such as a semiconductor substrate. In the present embodiment, the semiconductor substrate is a semiconductor wafer, such as a silicon wafer or other type of wafer. The target 26 is coated with a resist layer sensitive to the radiation beam, such as EUV light in the present embodiment. Various components including those described above are integrated and are operable to perform lithography exposing processes. In some embodiments, the lithography system 10 includes other modules or is integrated with (or coupled with) other modules.

The EUV lithography mask 18 and the method of fabricating the same are further described in accordance with some embodiments. In certain embodiments, the mask fabrication process includes a blank mask fabrication process and a mask patterning process. During the blank mask fabrication process, a blank mask is formed by depositing suitable layers (e.g., reflective multiple layers) on a suitable substrate. The blank mask is then patterned during the mask patterning process to achieve the desired design of a layer of an integrated circuit (IC). The patterned mask is then used to transfer circuit patterns (e.g., the design of a layer of an IC) onto a semiconductor wafer. The patterns are transferred over and over onto multiple wafers through various lithography processes. A set of masks is used to construct a complete IC.

The EUV lithography mask 18 includes a suitable structure, such as a binary intensity mask (BIM) and phase-shifting mask (PSM) in various embodiments. An example BIM includes absorptive regions (also referred to as opaque regions) and reflective regions, patterned to define an IC pattern to be transferred to the target. In the opaque regions, an absorber is present, and an incident light is almost fully absorbed by the absorber. In the reflective regions, the absorber is removed, and the incident light is diffracted by a multi-layer (multi-layer reflective structure). In certain embodiments, the PSM is an attenuated PSM (AttPSM) or an alternating PSM (AltPSM). An exemplary PSM includes a first reflective layer (such as a multi-layer reflective structure) and a second reflective layer patterned according to an IC pattern. In some examples, an AttPSM has a reflectivity of 2%-15% from its absorber, while an AltPSM has a reflectivity of larger than 50% from its absorber.

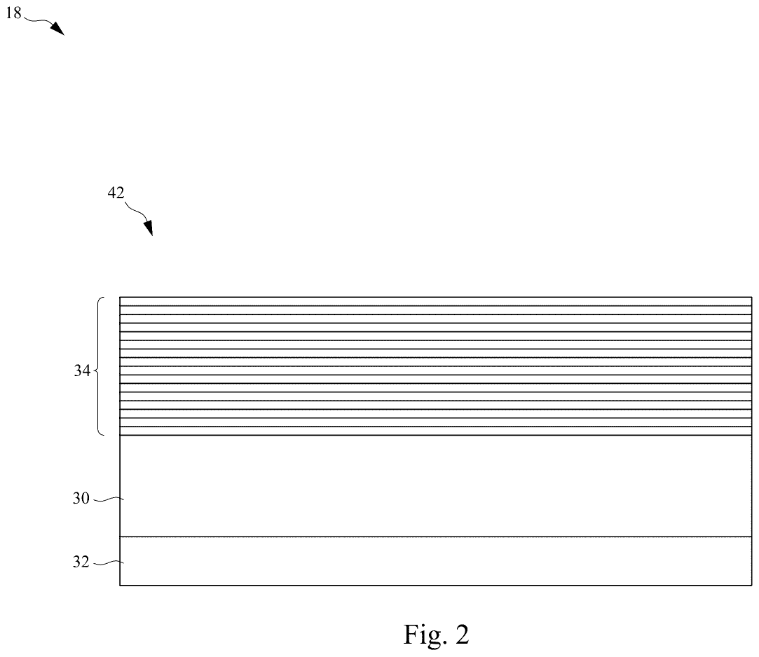

Referring to FIG. 2, the EUV lithography mask 18 in FIG. 1 is illustrated in more detail. The EUV lithography mask 18 includes a substrate 30. In certain embodiments, the substrate includes an LTEM with TiO₂ doped SiO₂, and/or other suitable low thermal expansion materials. In some embodiments, a conductive layer 32 is additionally disposed on an underside 42 (also referred to as a backside) of the LTEM substrate 30 for the electrostatic chucking purpose. In one example, the conductive layer 32 includes chromium nitride (CrN). In other embodiments, other suitable compositions are used, such as a tantalum-containing material.

The EUV lithography mask 18 includes a multi-layer reflective structure 34 disposed over a side 44 (also referred to as a front side) of the LTEM substrate 30. The multi-layer reflective structure 34 is selected such that it provides a high reflectivity to a selected radiation type/wavelength. The multi-layer reflective structure 34 includes a plurality of film pairs, such as Mo/Si film pairs (e.g., a layer of molybdenum above or below a layer of silicon in each film pair). Alternatively, the multi-layer reflective structure 34 includes Mo/Be film pairs or any materials with refractive index difference being highly reflective at EUV wavelengths.

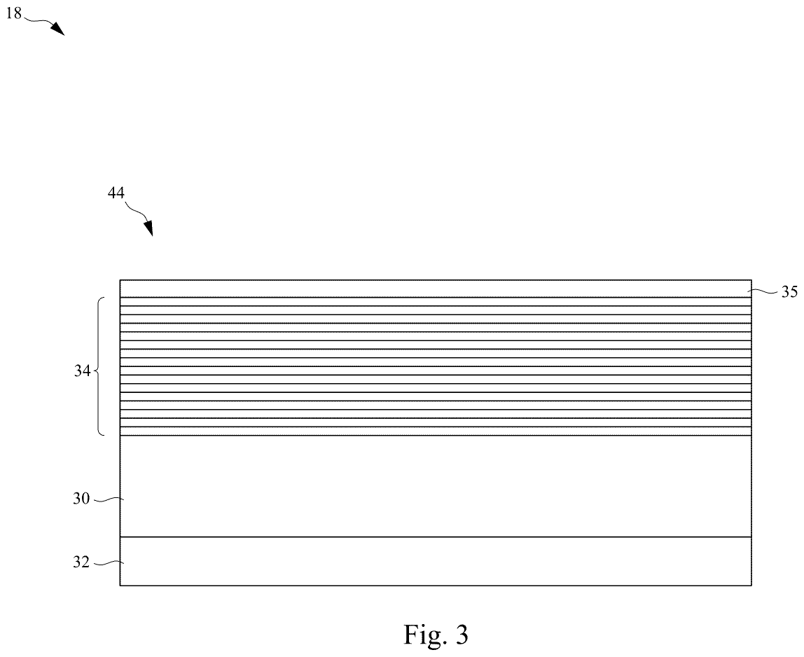

Referring now to FIG. 3, a capping layer 35 is formed over the multi-layer reflective structure 34. In some embodiments, the capping layer 35 is formed by a capping layer formation process including an epitaxial growth process, a CVD process (such as APCVD, LPCVD, LECVD, or PECVD), or a PVD process (such as electrically heated evaporation, pulsed laser deposition, electron-beam evaporation, molecular beam epitaxy, ion beam assisted evaporation, sputtering, arc evaporation, or ion beam deposition (IBD).

In some embodiments, the value of the thickness of the capping layer 35 is tunable by adjusting the various parameters of the formation process, for example, a time duration of deposition, etc. In some embodiments, the thickness is tuned to be in a range between about 1 nm and about 6 nm, for example between about 2 nm and about 5 nm. Such a thickness range for the capping layer 35 helps ensure that the capping layer 35 is sufficiently thick to adequately protect the multi-layer reflective structure 34 underneath, but not too thick to significantly affect the reflectivity of the multi-layer reflective structure 34. In some embodiments, the capping layer 35 has an amorphous structure and in other embodiments, the capping layer 35 has a polycrystalline structure with a grain size of about 1 to about 5 nm. In some embodiments, the material for the capping layer 35 is selected from one or more of Ru, RuO, RuNb, RuNbO, RuZr, RuZrN, RuRh, RuON, RuNbN, RuRhN, RuVO, RuV, or RuVN.

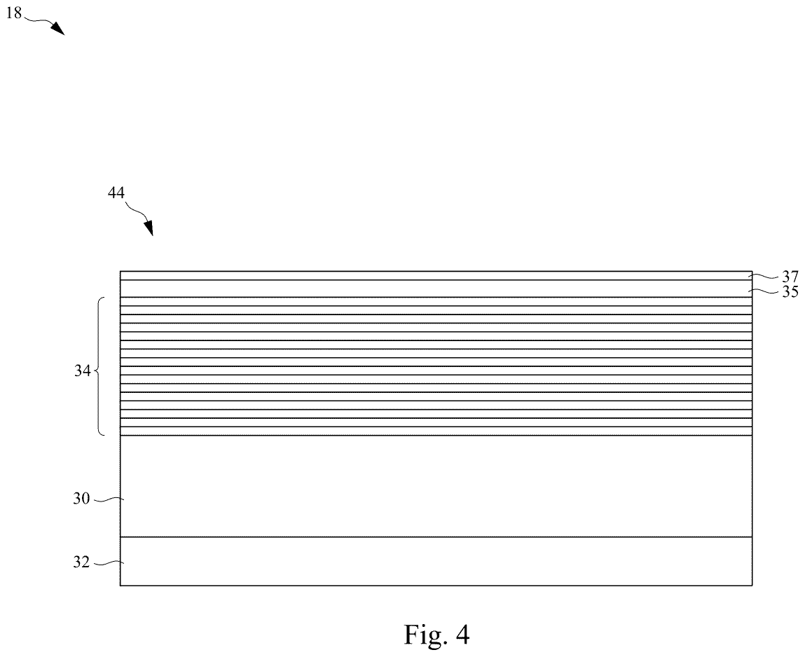

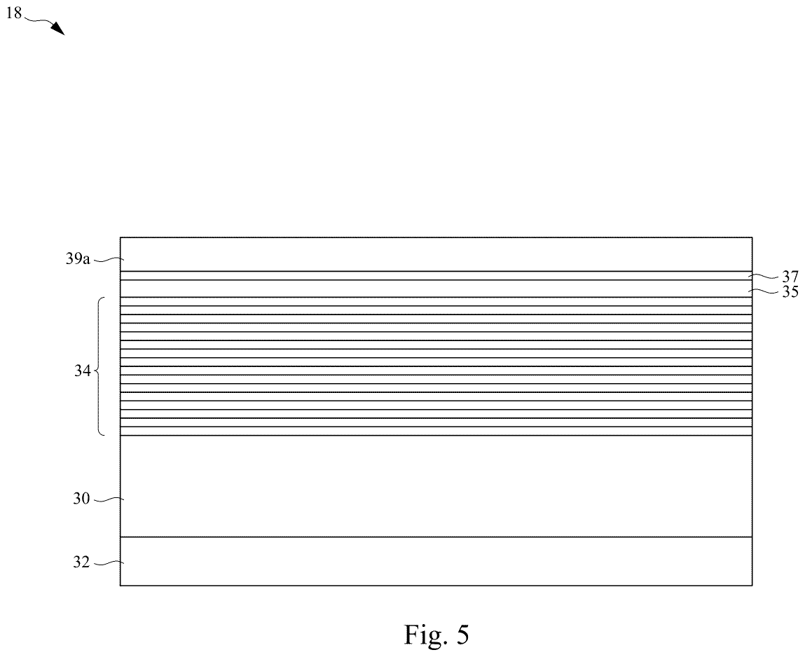

Referring now to FIG. 4, a buffer layer 37 is formed over the capping layer 35. In certain embodiments, the buffer layer 37 serves as an etching-stop layer in a patterning or repairing process of an overlying absorber layer 39 (FIG. 5). In some embodiments, the purpose of the buffer layer 37 is to protect the capping layer 35 during etching of the absorber layer 39. In some embodiments, the buffer layer 37 has different etching characteristics from the absorber layer 39. In some embodiments, the buffer layer 37 includes Ru, RuB, RuSi, RuCr Cr, CrO, CrN, Cr₂N, TaBO, TaBN, TaN, Ta₂O₅, TaO₂, TaO, Ta₂O, MoSi, MoSiN, MoSiO, SiN, SiON, SiO₂, SiCON, SiC, or SiCN. In some embodiments, the thickness range of the buffer layer 37 is about 2 to about 20 nm.

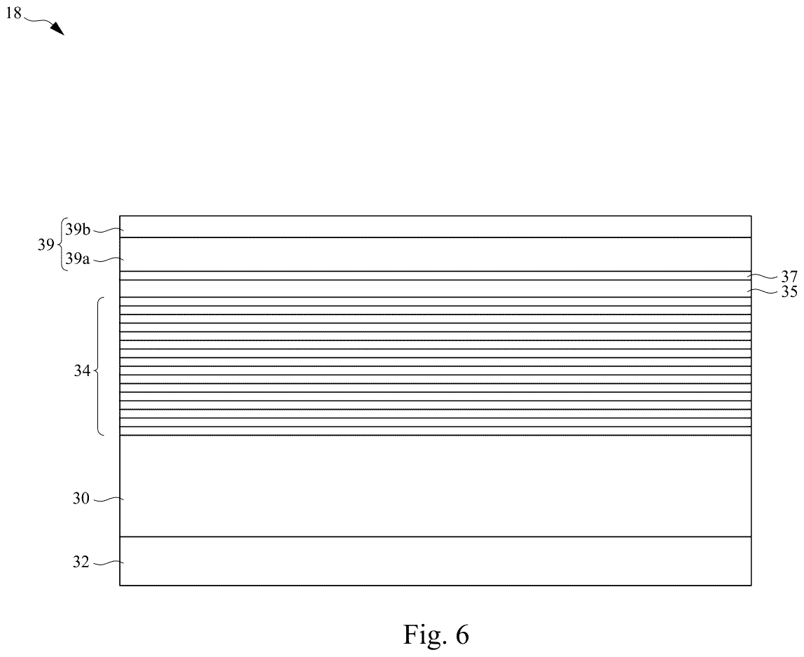

Referring now to FIG. 5, a first absorber layer 39a is formed over the buffer layer 37. In some embodiments, the absorber layer 39 is a bilayer including the first absorber layer 39a and second absorber layer 39b, as shown in FIG. 6. In certain embodiments, the absorber layer 39 absorbs the EUV radiation directed onto the EUV lithography mask 18. In various embodiments, the material of each absorber layer 39a and 39b comprises a pure element that is a non-alloyed element selected from platinum (Pt), palladium (Pd), gold (Au), iridium (Ir), osmium (Os), rhodium (Rh), ruthenium (Ru), indium (In), tellurium (Te), chromium (Cr), tungsten (W), molybdenum (Mo), tantalum (Ta), nickel (Ni), cobalt (Co), or titanium (Ti). The pure element is a primary component of each of the first absorber layer 39a and the second absorber layer 39b. In one embodiment, the first absorber layer 39a comprises pure elemental Ru, and the second absorber layer 39b comprises pure elemental Pt. As explained further below, in other embodiments, the first absorber layer 39a and/or the second absorber layer 39b can further include a dopant.

In some embodiments, the material of the first absorber layer 39a is different from the material of the second absorber layer 39b. In some embodiments, a combination of materials for the first absorber layer 39a and the second absorber layer 39b include Pt+Ru, Pt+Rh, Pt+Pd, Pt+Ir, Pt+Cr, Pt+W, Pt+Mo, Pd+Ru, Pd+Rh, Pd+Ir, Pd+Cr, Pd+W, Pd+Mo, Rh+Ir, Rh+Ru, Rh+Cr, Rh+W, Rh+Mo, Ru+Ir, Ru+Cr, Ru+W, or Ru+Mo. In certain embodiments, the overall thickness of the absorber layer 39 is about 1 nm to about 40 nm. In some embodiments, the thickness of the first absorber layer 39a is greater than the thickness of the second absorber layer 39b. In some embodiments, the thickness of the first absorber layer 39a is about 15 nm to about 25 nm and the thickness of the second absorber layer 39b is about 5 nm to about 15 nm. In other embodiments, the first absorber layer 39a and the second absorber layer 39b have the same thickness. In yet other embodiments, the thickness of the second absorber layer 39b is greater than the thickness of the first absorber layer 39a. In some embodiments, the absorber layer has a total thickness of about 40 nm or less to provide a thinner absorber layer that reduces the occurrence of mask three-dimensional effects.

In certain examples, the materials of the first absorber layer 39a and second absorber layer 39b are capable of withstanding harsh chemical and physical conditions during etching. In certain examples, the first absorber layer 39a includes Ru in a thickness range of about 14 to about 16 nm, the second absorber layer 39b includes Pt in a thickness range of about 12 to about 18 nm, and the buffer layer 37 comprises CrN in a thickness range of about 3 nm to about 5 nm. In certain embodiments, the total thickness of the first absorber layer 39a, the second absorber layer 39b, and the buffer layer 37 is about 40 nm or less. In other embodiments, the total thickness of the first absorber layer 39a, the second absorber layer 39b, and the buffer layer 37 is in a range of about 32 nm to 37 nm.

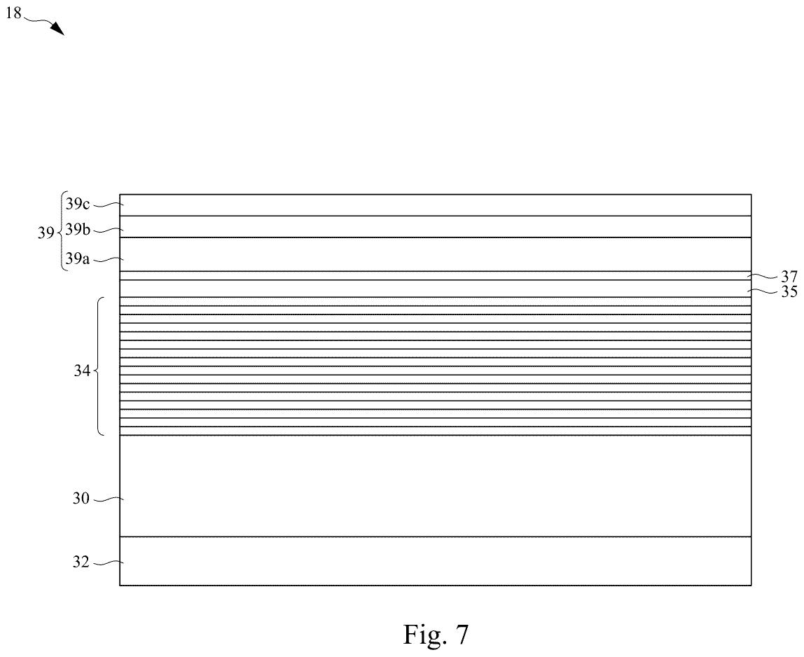

As shown in FIG. 7, in some embodiments, the absorber layer 39 includes a first absorber layer 39a, a second absorber layer 39b, and a third absorber layer 39c. In certain embodiments, the material for each of the first absorber layer 39a, the second absorber layer 39b, and the third absorber layer 39c is a pure element selected from Pt, Pd, Au, Ir, Os, Rh, Ru, In, Te, Cr, W, Mo, Ta, Ni, Co, or Ti. In certain embodiments, the material is different for each of the absorber layers 39a, 39b, and 39c. In another embodiment, the first absorber layer 39a comprises Ru at a thickness of about 5 to about 8 nm, the second absorber layer 39b comprises Pt at a thickness of about 15 to about 20 nm, the third absorber layer 39c comprises Ru at a thickness of about 6 to about 10 nm, and the buffer layer 37 comprises CrN at a thickness of about 3 nm to about 6 nm.

In yet a further embodiment, the first absorber layer 39a, at a thickness of about 5 to about 8 nm, comprises a RuPt alloy, the second absorber layer 39b comprises pure elemental Pt at a thickness of about 15 to about 20 nm, the third absorber layer 39c comprises pure elemental Ru at a thickness of about 6 to about 10 nm, and the buffer layer 37 comprises CrN at a thickness of about 3 nm to about 6 nm. In other embodiments, a dopant is included in one or more of the absorber layers 39a, 39b, and 39c and the dopant is selected from one or more of O, N, B, or ON, at a concentration of less than or equal to about 40 atomic % (at %), for example about 1 at %, about 5 at %, about 10 at %, about 20 at %, about 30 at %, or about 40 at %. In other embodiments, the dopant in one or more of the absorber layers 39a, 39b, and 39c is selected from one or more of Pt, Pd, Au, Ir, Os, Rh, Ru, In, Te, Cr, W, Mo, Ta, Ni, Co, or Ti at a concentration of less than or equal to about 40 atomic % (at %), for example about 1 at %, about 5 at %, about 10 at %, about 20 at %, about 30 at %, or about 40 at %.

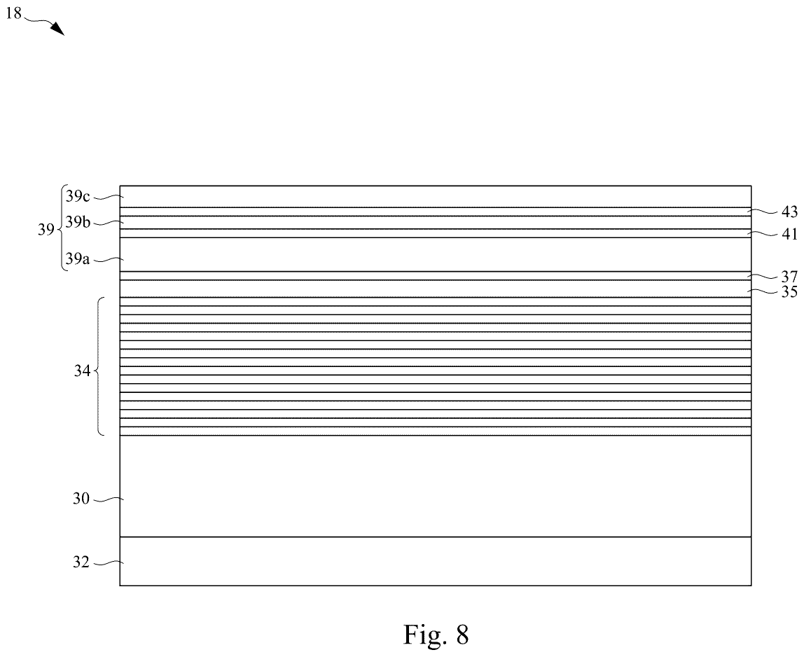

As shown in FIG. 8, one or more interdiffusion layers 41 and 43 are generated between the absorber layers 39a, 39b, and 39c as a result of the mixing of the elemental materials during layer formation. In one embodiment, the first absorber layer 39a comprises Ru at a thickness of about 5 to about 8 nm, the second absorber layer 39b comprises Pt at a thickness of about 15 to about 20 nm, the third absorber layer 39c comprises Ru at a thickness of about 6 to about 10 nm, the buffer layer 37 comprises CrN at a thickness of about 3 nm to about 6 nm, and the interdiffusion layers 41 and 43 comprise PtRu, wherein each of the interdiffusion layers 41 and 43 has a thickness of about 1 nm to about 7 nm.

In yet another embodiment, the first absorber layer 39a, at a thickness of about 5 to about 8 nm, comprises a RuPt alloy, the second absorber layer 39b comprises Pt at a thickness of about 15 to about 20 nm, the third absorber layer 39c comprises Ru at a thickness of about 6 to about 10 nm, the buffer layer 37 comprises CrN at a thickness of about 3 nm to about 6 nm, and each of the interdiffusion layers 41 and 43 comprise PtRu at a thickness of about 1 nm to about 7 nm.

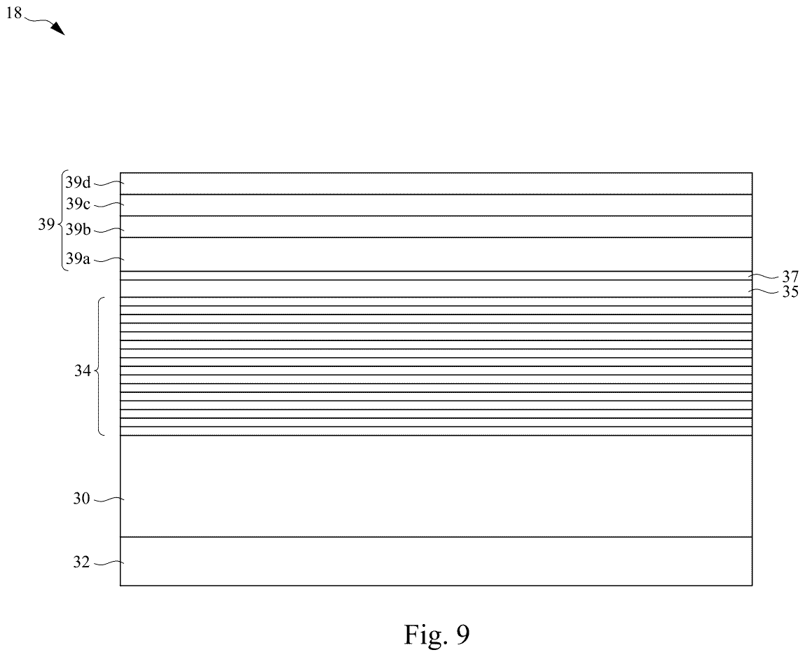

In other embodiments, as shown in FIG. 9, four absorber layers 39a, 39b, 39c, and 39d are provided. In some embodiments, the microstructure of each of the absorber layers 39a, 39b, 39c, and 39d is polycrystalline. In other embodiments, the microstructure of each of the absorber layers 39a, 39b, 39c, and 39d is amorphous. In certain embodiments, materials for the absorber layers 39d, 39c, and 39b are selected from pure elements selected from Pt, Pd, Au, Ir, Os, Rh, Ru, In, Te, Cr, W, Mo, Ta, Ni, Co, or Ti, and the absorber layer 39a comprises an alloy. In some embodiments, the alloy of the absorber layer 39a comprises RuPt. In other embodiments, a dopant is introduced in one or more of the absorber layers 39a, 39b, 39c, or 39d. The dopant is selected from one or more of O, N, B, ON or BN at a concentration of less than or equal to about 40 atomic % (at %), for example about 1 at %, about 5 at %, about 10 at %, about 20 at %, about 30 at %, or about 40 at %. In other embodiments, the dopant is selected from one or more of Pd, Au, Ir, Os, Rh, Ru, In, Te, Cr, W, Mo, Ta, and Ti at a concentration of less than or equal to about 1 at %, for example about 0.01 at %, about 0.05 at %, about 0.2 at %, about 0.3 at %, about 0.5 at %, or about 1 at %. In some embodiments, the total thickness of the absorber layers 39a, 39b, 39c, and 39d is less than about 40 nm. In other embodiments, one or more interdiffusion layers 41 and 43 (FIG. 8) are formed between adjacent absorber layers.

In certain embodiments of the present disclosure, the absorber layer 39 has an index of refraction of about 0.9 or less. In some embodiments, the absorber layer 39 has a refraction index in a range of about 0.88 to about 0.9. In other embodiments, the absorber layer 39 has an extinction coefficient in a range of 0.02 to about 0.06. In other embodiments, the image log slope (ILS) of the absorber layer 39 is about 161.0 to about 161.3 μm⁻¹. The ILS is a measure of the image contrast and resolution capability of the mask that can be influenced by several factors including the material properties and thickness of the absorber layer 39. In yet other embodiments, the normalized exposure energy (NEE) of the EUV mask ranges between about 98.3 to about 99.9 arbitrary units (A.U.). The NEE represents the energy to properly expose the photoresist on the wafer, normalized to a standard reference. In certain embodiments, absorber layers comprising materials with a low refraction index (e.g., less than about 0.9), can result in a thinner absorber layer (e.g, less than about 40 nm) which in turn can reduce the occurrence of mask three-dimensional effects, improve ILS, and reduce exposure energy.

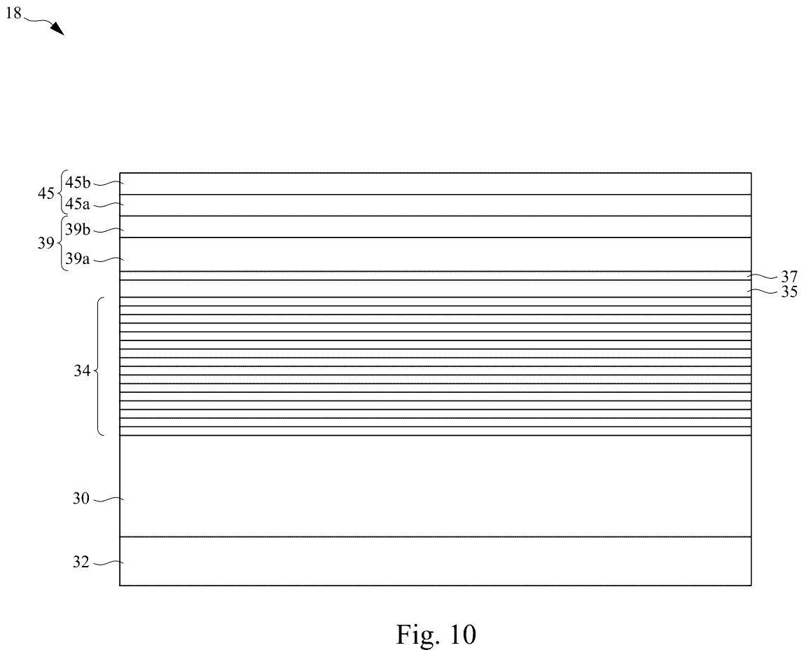

Referring to FIG. 10, a plurality of hard masks 45 are formed over the absorber layer 39. In certain embodiments, a first hard mask 45a is formed over absorber layer 39b. In some embodiments, the thickness of the first hard mask 45a is between about 2 and about 20 nm. In some embodiments, a material for the first hard mask 45a is selected from TaBO, TaBN, TaN, Ta₂O₅, TaO₂, TaO, Ta₂O, MoSi, MoSiN, MoSiO, SiN, SiON, SiO₂, SiCON, SiC, SiCN, or CrN. In some embodiments, the second hard mask 45b comprises a material selected from GaN, CrON, CrCON, SiO, SiCO, Y₂O₃, SiCO, or SiCON. In some embodiments, the thickness of the second hard mask 45b is between about 2 and about 20 nm. In certain embodiments, the deposition technique for depositing the hard mask layers 45a and 45b are selected from sputter deposition, chemical vapor deposition (CVD), plasma-enhanced CVD (PECVD), atomic layer deposition (ALD), or physical vapor deposition (PVD).

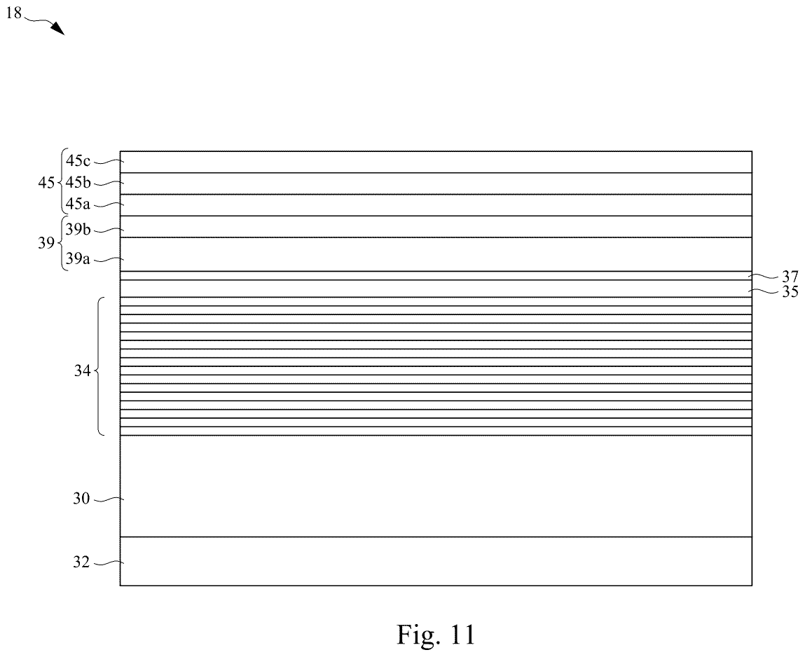

In some embodiments, as shown in FIG. 11, three hard masks 45a, 45b, and 45c are formed, wherein the first hard mask 45a comprises a material selected from TaBN, TaN, MoSi, MoSiN, SiN, SiC, SiCN, or CrN. The second hard mask 45b comprises a material selected from TaBO, Ta₂O₅, TaO₂, TaO, Ta₂O, MoSiO, SiON, SiO₂, or SiCON. The third hard mask 45c comprises a material selected from GaN, CrON, CrCON, SiO, SiCO, Y₂O₃, SiCO, or SiCON. The thickness of each hard mask 45a, 45b, and 45c is in a range of about 2 to about 20 nm. The capping layer 35 comprises a material selected from Ru, RuO, RuNb, RuNbO, RuZr, RuZrN, RuRh, RuON, RuNbN, RuRhN, RuVO, RuV, or RuVN, at a thickness of about 2 nm to about 5 nm. The buffer layer 37 comprises a material selected from TaBN, TaN, MoSi, MoSiN, SiN, SiC, SiCN, or CrN, at a thickness of about 2 nm to about 20 nm.

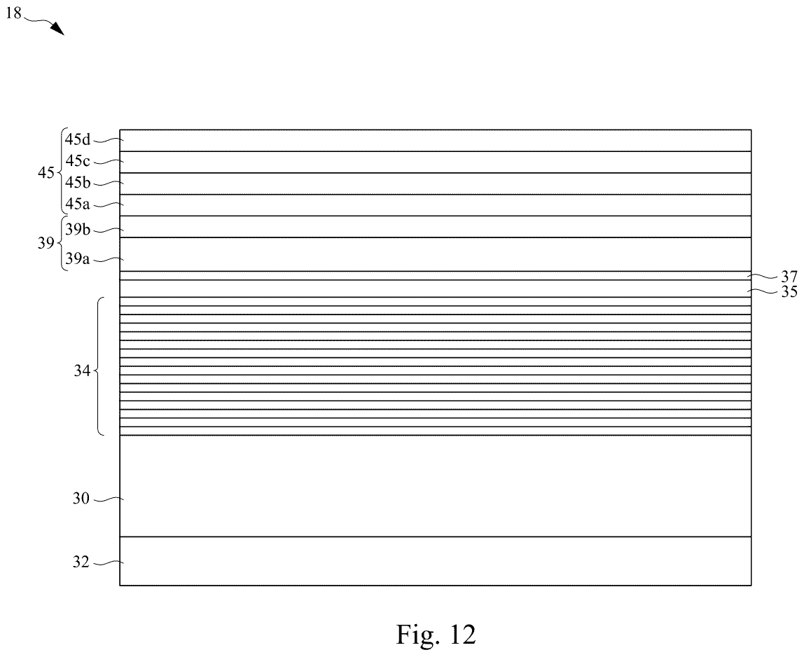

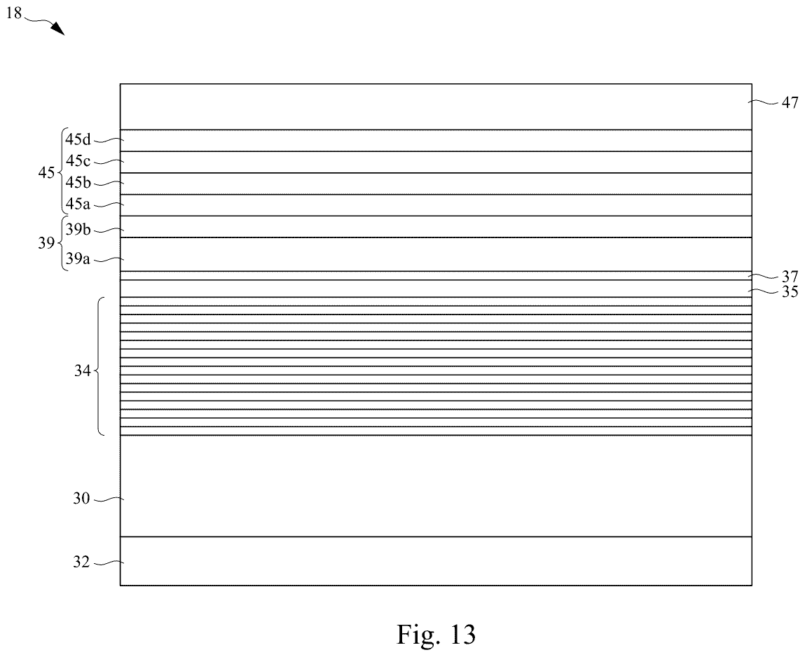

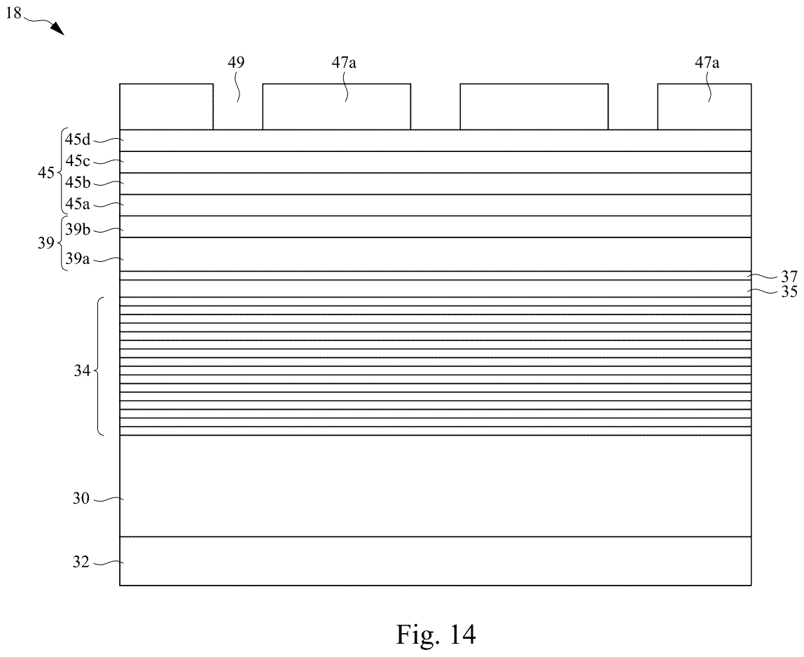

In some embodiments, as shown in FIG. 12, four hard masks 45a, 45b, 45c, and 45d are formed, wherein the first hard mask 45a comprises a material selected from CrN or Cr₂N. The second hard mask 45b comprises a material selected from TaBN, TaN, MoSi, MoSiN, SiN, SiC, SiCN, or CrN. The third hard mask 45c comprises a material selected from TaBO, Ta₂O₅, TaO₂, TaO, Ta₂O, MoSiO, SiON, SiO₂, and SiCON. The fourth hard mask 45d comprises a material selected from CrON, CrCON, SiO, SiCO, Y₂O₃, SiCO, or SiCON. The thickness of each hard mask 45a, 45b, and 45c is in a range of about 2 to about 20 nm. The capping layer 35 comprises a material selected from Ru, RuO, RuNb, RuNbO, RuZr, RuZrN, RuRh, RuON, RuNbN, RuRhN, RuVO, RuV, or RuVN, at a thickness of about 2 nm to about 5 nm. The buffer layer 37 comprises a material selected from CrN or Cr₂N, at a thickness of about 2 nm to about 20 nm. In FIG. 12, the first absorber layer 39a and the second absorber layer 39b are comprised of a pure element selected from Pt, Pd, Au, Ir, Os, Rh, Ru, In, Te, Cr, W, Mo, Ta, Ni, Co, or Ti. In some embodiments, the material for the first absorber layer 39a is different from the material of the second absorber layer 39b. The thickness of each absorber layer 39a and 39b is about 1 to about 30 nm. In some embodiments, the materials for each absorber layer 39a and 39b comprise a pure element or an element doped with N, O, B, ON, or BN at a concentration of less than or equal to about 40 at %, for example about 2 at %, about 5 at %, about 10 at %, about 20 at %, about 30 at %, or about 40 at %. In other embodiments, the dopant is selected from one or more of Pd, Au, Ir, Os, Rh, Ru, In, Te, Cr, W, Mo, Ta, and Ti at a concentration of less than or equal to about 1 at %, for example about 0.01 at %, about 0.05 at %, about 0.2 at %, about 0.3 at %, about 0.5 at %, or about 1 at %. FIGS. 13-22 are cross-sectional side views of a process for manufacturing a patterned lithography mask, according to embodiments of the present disclosure. Referring now to FIG. 13, a photoresist layer 47 is formed over the uppermost hard mask layer 45d by a spin-coating process. In some examples, the photoresist layer 47 is an EUV photoresist (e.g., sensitive to radiation in the EUV range). As shown in FIG. 14, the photoresist layer 47 is patterned into a plurality of portions 47a separated by a plurality of openings 49. In some embodiments, the patterning of the photoresist layer 47 includes an electron beam (E-beam) exposure process, a post-exposure bake process, and a photoresist developing process.

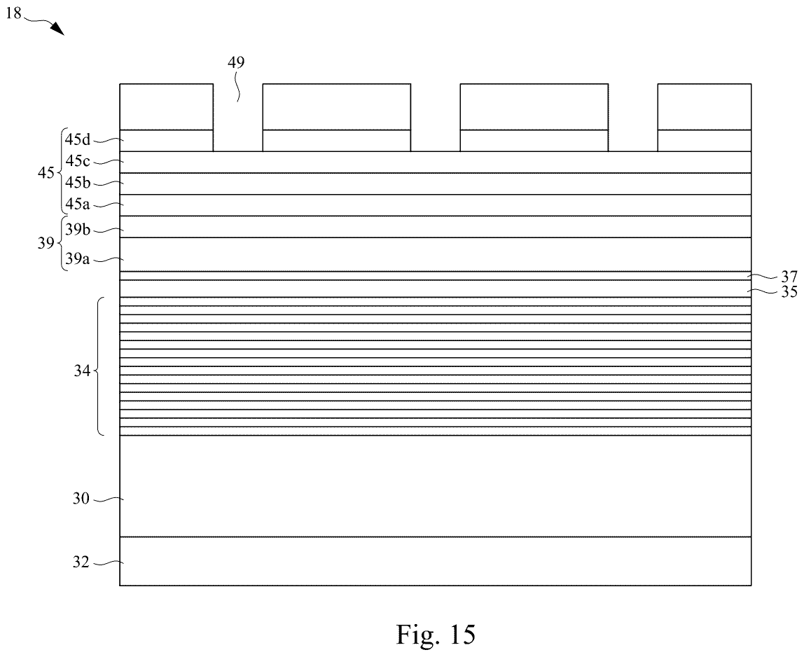

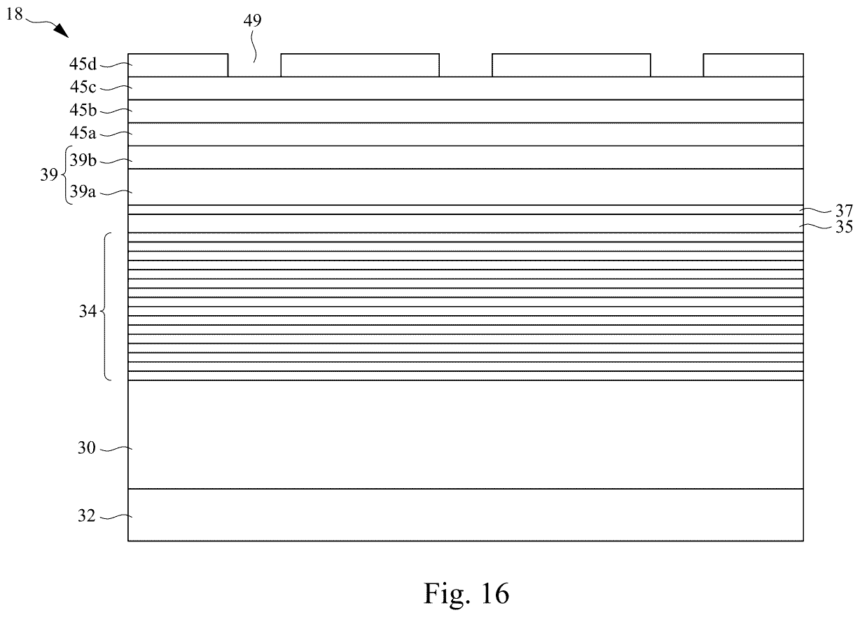

Referring now to FIG. 15, an etching process is performed, with the patterned photoresist layer 47 serving as an etching mask. In other words, the openings 49 are vertically extended through the fourth hard mask 45d until portions of the third hard mask 45c are exposed by the openings 49. In some embodiments, the etching process includes a dry etching process. In certain embodiments, as shown in FIG. 16, additional processing is performed to remove the patterned photoresist layer 47. In some embodiments, a photoresist removal process (not shown) includes a photoresist stripping or ashing process.

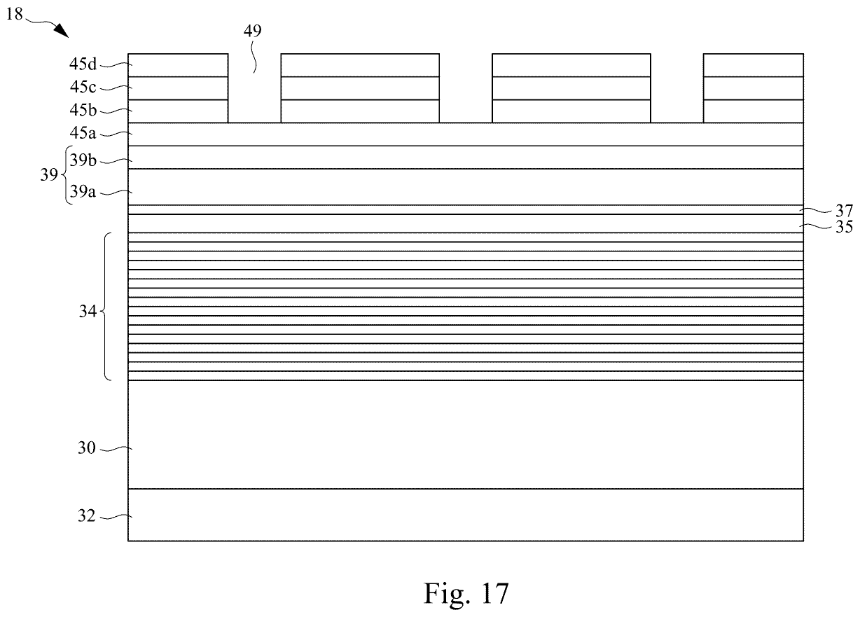

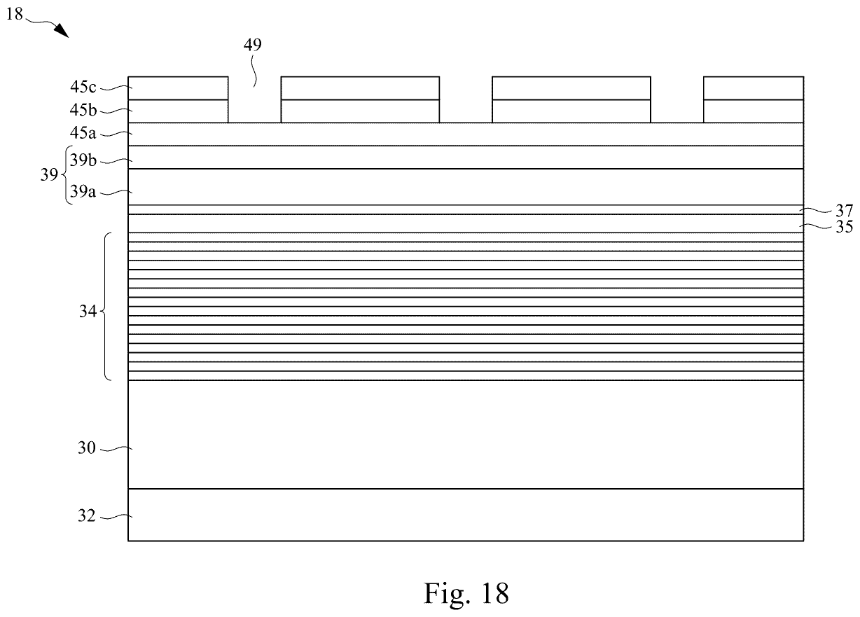

As shown in FIG. 17, additional etching is performed, with the patterned hard mask 45d serving as an etching hard mask. In other words, the openings 49 are vertically extended through the third and second hard masks 45c and 45b until portions of the first hard mask 45a are exposed by the openings 49. As shown in FIG. 18, the fourth hard mask 45d is removed. In some embodiments, the fourth hard mask 45d is removed by a wet or dry chemical processing.

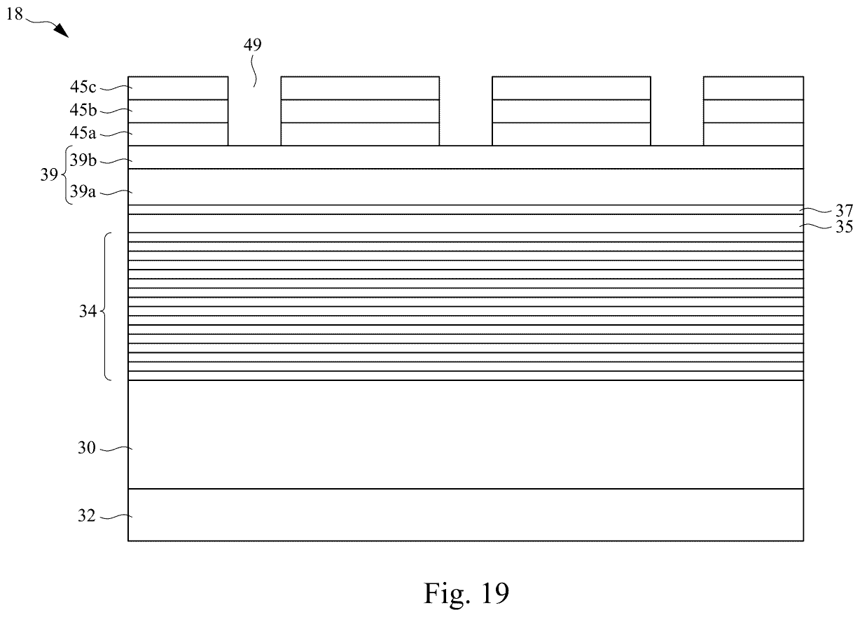

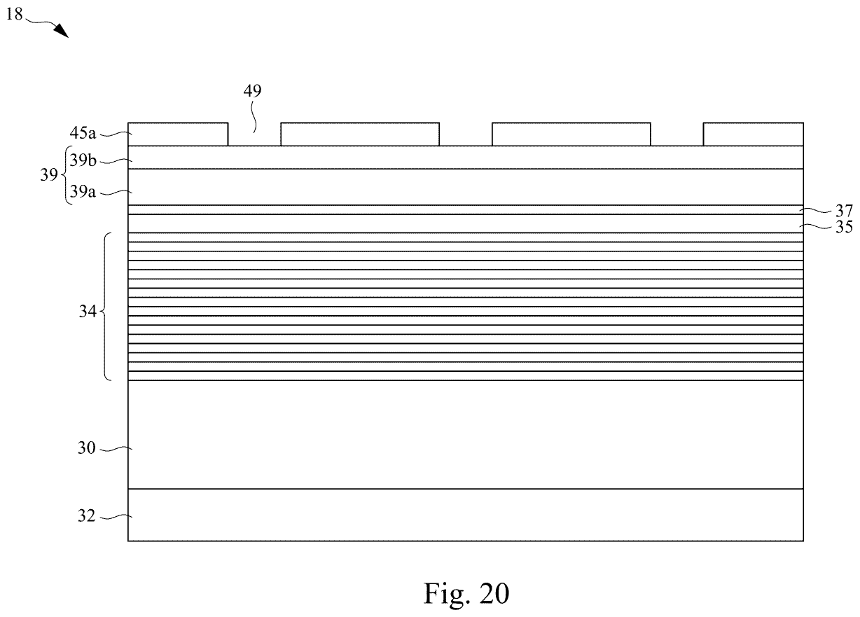

As shown in FIG. 19, additional etching is performed, with the patterned hard mask 45c serving as an etching hard mask. In other words, the openings 49 are vertically extended through the second and first hard masks 45b and 45a until portions of the second absorber layer 39b are exposed by the openings 49. As shown in FIG. 20, the second and third hard masks 45b and 45c are removed. In some embodiments, the second and third hard masks 45b and 45c are removed by wet or dry chemical processing.

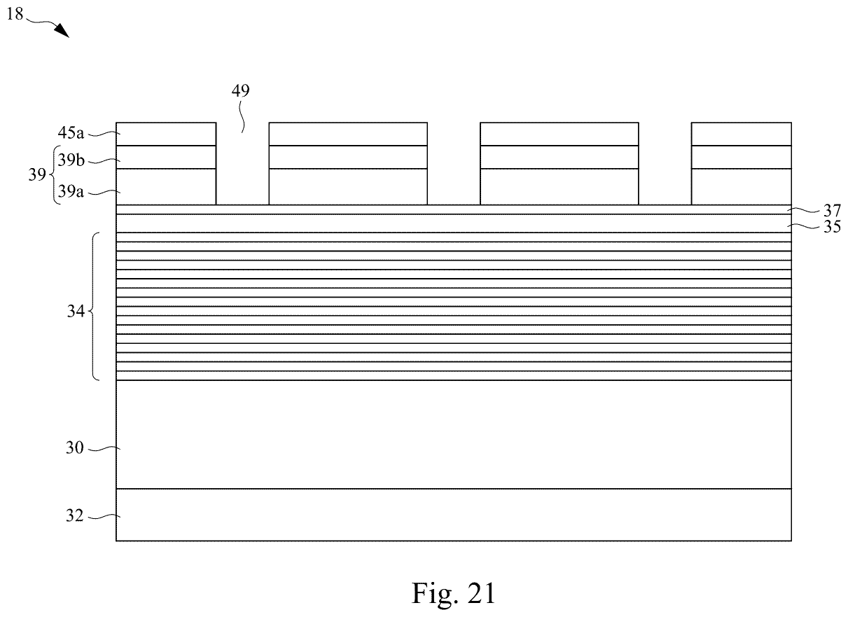

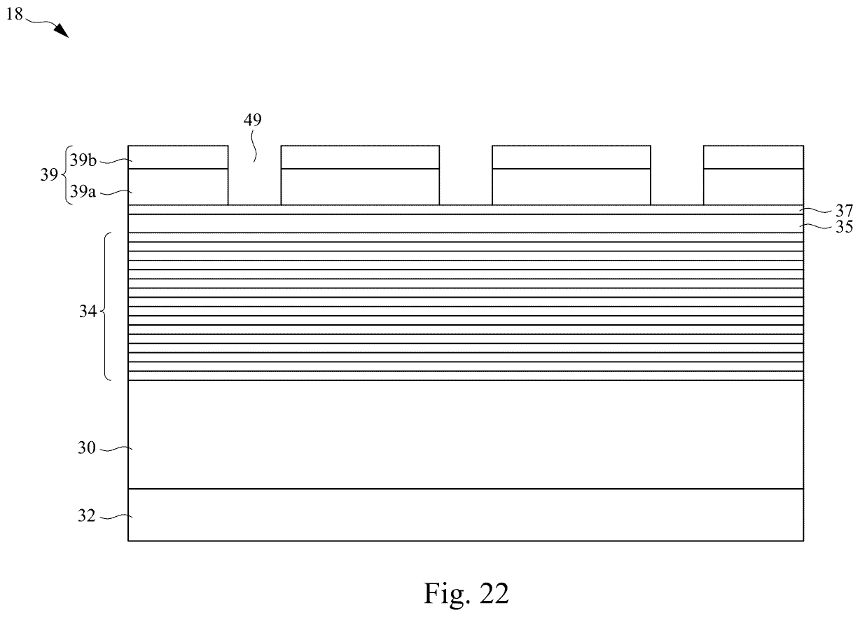

Referring now to FIG. 21, an etching process is performed, with the patterned first hard mask 45a serving as an etching mask. In other words, the openings 49 are vertically extended through absorber layers 39a and 39b until portions of the buffer layer 37 are exposed by the openings 49. As shown in FIG. 22, additional processing is performed to remove the patterned hard mask 45a. Moreover, in certain embodiments, one or more cleaning processes to clean the patterned EUV lithography mask 18, for example, to remove contaminant particles disposed on the patterned EUV lithography mask 18.

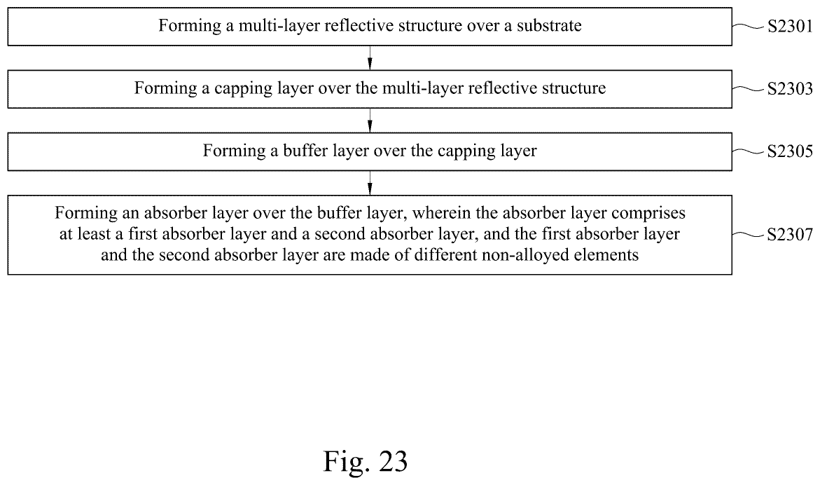

FIG. 23 is a flowchart for a method of fabricating a lithography mask, according to various aspects of the present disclosure. The method includes the step of forming a multi-layer reflective structure over a substrate (S2301). The method includes the step of forming a capping layer over the multi-layer reflective structure (S2303). The method includes the step of forming a buffer layer over the capping layer (S2305). The method further includes forming an absorber layer over the buffer layer (S2307), wherein the absorber layer comprises at least a first absorber layer and a second absorber layer, each comprising a non-alloyed element selected from Pt, Pd, Au, Ir, Os, Rh, Ru, In, Te, Cr, W, Mo, Ta, Ni, Co, or Ti, and the first absorber layer and the second absorber layer are made of different non-alloyed elements.

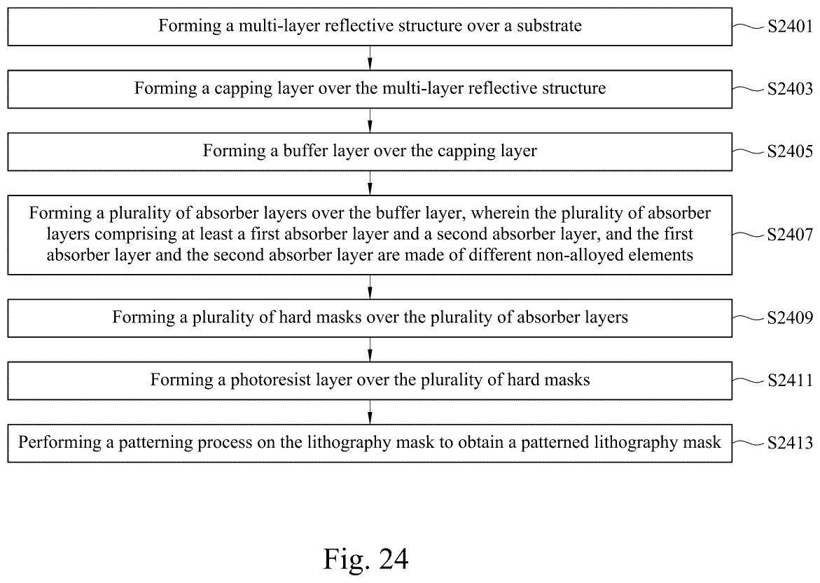

FIG. 24 is a flowchart for manufacturing a patterned lithography mask, according to various aspects of the present disclosure. The method includes the step of forming a multi-layer reflective structure over a substrate (S2401). The method includes the step of forming a capping layer over the multi-layer reflective structure (S2403). The method includes the step of forming a buffer layer over the capping layer (S2405). The method further includes forming a plurality of absorber layers over the buffer layer (S2407), wherein the plurality of absorber layers comprising at least a first absorber layer and a second absorber layer, each comprising a non-alloyed element selected from Pt, Pd, Au, Ir, Os, Rh, Ru, In, Te, Cr, W, Mo, Ta, Ni, Co, or Ti, and the first absorber layer and the second absorber layer are made of different non-alloyed elements. The method further includes the step of forming a plurality of hard masks over the plurality of absorber layers (S2409). The method includes the step of forming a photoresist layer over the plurality of hard masks (S2411). The method includes the step of performing a patterning process on the lithography mask to obtain a patterned lithography mask (S2413).

In summary, the present disclosure forms a multi-layer absorber layer for an EUV lithography mask. Based on the above discussions, it can be seen that the materials of the multi-layer absorber layer of the present disclosure offer advantages over conventional EUV masks. It is understood, however, that other embodiments may offer additional advantages and not all advantages are necessarily disclosed herein, and that no particular advantage is required for all embodiments. One advantage is that the EUV lithography mask of the present disclosure reduces mask three-dimensional effects including light shadowing by providing a thinner absorber layer compared to conventional EUV lithography masks. Other advantages include a multi-layer absorber layer that comprises materials that permit easier adjustment of refraction index and low extinction coefficient factors. Yet other advantages include the formation of a thinner absorber layer compared to conventional EUV lithography masks helps reduce exposure energy and improves the image quality of the mask.

One aspect of the present disclosure pertains to a method of fabricating a lithography mask. The method includes forming a multi-layer reflective structure over a substrate. The method includes forming a capping layer over the multi-layer reflective structure. The method includes forming a buffer layer over the capping layer. The method further includes forming an absorber layer over the buffer layer. The absorber layer includes at least a first absorber layer and a second absorber layer, each including a non-alloyed element selected from Pt, Pd, Au, Ir, Os, Rh, Ru, In, Te, Cr, W, Mo, Ta, Ni, Co, or Ti, and the first absorber layer and the second absorber layer are made of different non-alloyed elements.

In some embodiments, the total thickness of the absorber layer is 40 nm or less. In other embodiments, one or both of the first absorber layer and second absorber layer further comprise a dopant selected from at least one of N, O, B, or ON. In some embodiments, the concentration of the dopant is 1 to 40 at. %. In some embodiments, the absorber layer is a polycrystalline structure, while in other embodiments, the absorber layer is an amorphous structure. In some embodiments, a third absorber layer is formed over the second absorber layer, wherein the third absorber layer is made of a different material than the second absorber layer. In some embodiments, the buffer layer comprises a material selected from Ru, RuB, RuSi, Cr, CrO, CrN, Cr₂N, TaBO, TaBN, TaN, Ta₂O₅, TaO₂, TaO, Ta₂O, MoSi, MoSiN, MoSiO, SiN, SiON, SiO₂, SiCON, SiC, or SiCN. In other embodiments, the first absorber layer includes Ru, the second absorber layer includes Pt, and the buffer layer includes CrN. In some embodiments, an interdiffusion layer is disposed between the first absorber layer and the second absorber layer.

Another aspect of the present disclosure pertains to a method of manufacturing a patterned lithography mask. The method includes forming a multi-layer reflective structure over a substrate. The method includes the step of forming a capping layer over the multi-layer reflective structure. The method includes the step of forming a buffer layer over the capping layer. The method further includes forming a plurality of absorber layers over the buffer layer. The plurality of absorber layers includes at least a first absorber layer and a second absorber layer, each comprising a non-alloyed element selected from Pt, Pd, Au, Ir, Os, Rh, Ru, In, Te, Cr, W, Mo, Ta, Ni, Co, or Ti. The first absorber layer and the second absorber layer are made of different non-alloyed elements. The method further includes forming a plurality of hard masks over the plurality of absorber layers. The method includes forming a photoresist layer over the plurality of hard masks. The method further includes performing a patterning process on the lithography mask to obtain a patterned lithography mask.

In some embodiments, the first absorber layer includes Ru, the second absorber layer includes Pt, and the buffer layer includes CrN. In other embodiments, a third absorber layer is formed over the second absorber layer, wherein the third absorber layer comprises Ru. In other embodiments, an interdiffusion layer comprising PtRu is disposed between the second absorber layer and the third absorber layer. In certain embodiments, the thickness of the interdiffusion layer is between 1 and 5 nm. In other embodiments, the total thickness of the plurality of absorber layers is 40 nm or less.

Yet another aspect of the present disclosure pertains to a lithography mask. The mask includes a substrate and a multi-layer reflective structure disposed over the substrate. The mask includes a capping layer disposed over the multi-layer reflective structure. Further, the mask includes a buffer layer disposed over the capping layer and an absorber layer disposed over the buffer layer. The absorber layer includes at least a first absorber layer and a second absorber layer, each comprising a non-alloyed element selected from Pt, Pd, Au, Ir, Os, Rh, Ru, In, Te, Cr, W, Mo, Ta, Ni, Co, or Ti. The first absorber layer and the second absorber layer are made of different non-alloyed elements.

In some embodiments, one or both of the first absorber layer and second absorber layer further include a dopant selected from at least one of N, O, B, or ON. In some embodiments, an interdiffusion layer is disposed between the first absorber layer and the second absorber layer. In other embodiments, the buffer layer comprises a material selected from Ru, RuB, RuSi, Cr, CrO, CrN, Cr₂N, TaBO, TaBN, TaN, Ta₂O₅, TaO₂, TaO, Ta₂O, MoSi, MoSiN, MoSiO, SiN, SiONB, SiO₂, SiCON, SiC, or SiCN.

The foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure and that they may make various changes, substitutions, and alterations herein without departing from the spirit and scope of the present disclosure.

What is claimed is:

1. A method of fabricating a lithography mask, comprising:
forming a multi-layer reflective structure over a substrate;
forming a capping layer over the multi-layer reflective structure;
forming a buffer layer over the capping layer; and
forming an absorber layer over the buffer layer,
wherein the absorber layer comprises at least a first absorber layer and a second absorber layer, each comprising a non-alloyed element selected from platinum (Pt), palladium (Pd), gold (Au), iridium (Ir), osmium (Os), rhodium (Rh), ruthenium (Ru), indium (In), tellurium (Te), chromium (Cr), tungsten (W), molybdenum (Mo), tantalum (Ta), nickel (Ni), cobalt (Co), or titanium (Ti), and
the first absorber layer and the second absorber layer are made of different non-alloyed elements.

2. The method of claim 1, wherein a total thickness of the absorber layer is 40 nm or less.

3. The method of claim 1, wherein one or both of the first absorber layer and second absorber layer further comprise a dopant selected from at least one of nitrogen (N), oxygen (O), boron (B), or oxynitride (ON).

4. The method of claim 3, wherein a concentration of the dopant is 1 to 40 atomic percent (at. %).

5. The method of claim 1, wherein the absorber layer is a polycrystalline structure.

6. The method of claim 1, wherein the absorber layer is an amorphous structure.

7. The method of claim 1, further comprises: forming a third absorber layer over the second absorber layer, wherein the third absorber layer is made of a different material than the second absorber layer.

8. The method of claim 1, wherein the buffer layer comprises a material selected from Ru, RuB, RuSi, RuCr, Cr, CrO, CrN, Cr₂N, TaBO, TaBN, TaN, Ta₂O₅, TaO₂, TaO, Ta₂O, MoSi, MoSiN, MoSiO, SiN, SiON, SiO₂, SiCON, SiC, or SiCN.

9. The method of claim 1, wherein the first absorber layer comprises Ru, the second absorber layer comprises Pt, and the buffer layer comprises CrN.

10. The method of claim 1, wherein an interdiffusion layer is disposed between the first absorber layer and the second absorber layer.

11. A method of manufacturing a lithography mask, comprising:
forming a multi-layer reflective structure over a substrate;
forming a capping layer over the multi-layer reflective structure;
forming a buffer layer over the capping layer;
forming a plurality of absorber layers over the buffer layer, the plurality of absorber layers comprising at least a first absorber layer and a second absorber layer, each comprising a non-alloyed element selected from platinum (Pt), palladium (Pd), gold (Au), iridium (Ir), osmium (Os), rhodium (Rh), ruthenium (Ru), indium (In), tellurium (Te), chromium (Cr), tungsten (W), molybdenum (Mo), tantalum (Ta), nickel (Ni), cobalt (Co), or titanium (Ti),
wherein the first absorber layer and the second absorber layer are made of different non-alloyed elements;
forming a plurality of hard masks over the plurality of absorber layers;
forming a photoresist layer over the plurality of hard masks; and
performing a patterning process on the lithography mask to obtain a patterned lithography mask.

12. The method of claim 11, wherein the first absorber layer comprises Ru, the second absorber layer comprises Pt, and the buffer layer comprises CrN.

13. The method of claim 12, further comprising forming a third absorber layer over the second absorber layer, wherein the third absorber layer comprises Ru.

14. The method of claim 13, wherein an interdiffusion layer comprising PtRu is disposed between the second absorber layer and the third absorber layer.

15. The method of claim 14, wherein a thickness of the interdiffusion layer is between 1 and 5 nanometers (nm).

16. The method of claim 11, wherein a total thickness of the plurality of absorber layers is 40 nm or less.

17. A lithography mask, comprising:
a substrate;
a multi-layer reflective structure disposed over the substrate;
a capping layer disposed over the multi-layer reflective structure;
a buffer layer disposed over the capping layer; and
an absorber layer disposed over the buffer layer,
wherein the absorber layer comprises at least a first absorber layer and a second absorber layer, each comprising a non-alloyed element selected from platinum (Pt), palladium (Pd), gold (Au), iridium (Ir), osmium (Os), rhodium (Rh), ruthenium (Ru), indium (In), tellurium (Te), chromium (Cr), tungsten (W), molybdenum (Mo), tantalum (Ta), nickel (Ni), cobalt (Co), or titanium (Ti),
wherein the first absorber layer and the second absorber layer are made of different non-alloyed elements.

18. The mask of claim 17, wherein one or both of the first absorber layer and second absorber layer further comprises a dopant selected from at least one of nitrogen (N), oxygen (O), boron (B), oxynitride (ON), or boron nitride (BN).

19. The mask of claim 17, wherein an interdiffusion layer is disposed between the first absorber layer and the second absorber layer.

20. The mask of claim 17, wherein the buffer layer comprises a material selected from Ru, RuB, RuSi, Cr, CrO, CrN, Cr₂N, TaBO, TaBN, TaN, Ta₂O₅, TaO₂, TaO, Ta₂O, MoSi, MoSiN, MoSiO, SiN, SiON, SiO₂, SiCON, SiC, or SiCN.
